(19) United States
(12) Patent Application Publication
(10) Pub. No.: US 2015/0357200 A1
(43) Pub. Date: Dec. 10, 2015

(54) DRY ETCHING METHOD

(71) Applicant: ZEON CORPORATION, Tokyo (JP)

(72) Inventor: Hirotoshi Inui, Tokyo (JP)

(73) Assignee: ZEON CORPORATION, Tokyo (JP)

(21) Appl. No.: 14/655,861

(22) PCT Filed: Dec. 27, 2013
(86) PCT No.: PCT/JP2013/085091

§ 371 Date: Jun. 26, 2015

(30) Foreign Application Priority Data
Dec. 27, 2012 (JP) 2012-284353

(51) Int. Cl. H01L 21/311

(52) U.S. Cl. CPC H01L 21/31116; H01L 21/31144

(57) ABSTRACT

The present invention is an etching method comprising etching a multilayered laminate film that includes at least one silicon oxide film layer and at least one silicon nitride film layer using an etching gas, the etching method simultaneously etching both the silicon oxide film layer and the silicon nitride film layer, the etching gas comprising a linear saturated fluorohydrocarbon compound represented by a formula (1): CₓH_{y}F_{z} (wherein x is 4, y is an integer equal to or larger than 4, and z is a positive integer, provided that y+z is 10). According to the present invention, it is possible to etch even a multilayered laminate film while ensuring high selectivity with respect to the mask and an excellent pattern shape, and preventing a situation in which contact holes are clogged by a deposited film.

### TECHNICAL FIELD

The present invention relates to an etching method that etches a multilayered laminate film that includes a silicon oxide film layer and a silicon nitride film layer using an etching gas that includes a specific fluorine compound.

### BACKGROUND ART

A semiconductor production process includes a step that etches a laminate film that includes a silicon oxide film and a silicon nitride film using an etching gas through a resist or an organic film used as a mask.

For example, Patent Document 1 discloses a method that etches a laminate film that includes at least one silicon oxide film layer and at least one silicon nitride film layer using a fluorohydrocarbon compound having 3 to 5 carbon atoms as an etching gas, the method simultaneously etching both the silicon oxide film layer and the silicon nitride film layer. In the examples of Patent Document 1, a laminate film that includes one silicon oxide film layer and one silicon nitride film layer is etched using 1,3,3,4,4,5,5-heptafluorocyclopentene (C₅HF₇) (i.e., a cyclic compound having 5 carbon atoms) or 1,1,1,3,4,4,5,5,5-nonafluoro-2-pentene (C₅HF₉) (i.e., a linear compound having 5 carbon atoms). Patent Document 1 states that the selectivity of the two-layer film with respect to the resist is improved, and the contact hole pattern shape is also improved using the method disclosed in Patent Document 1.

### RELATED-ART DOCUMENT

### Patent Document

Patent Document 1: JP-A-2008-300616

### SUMMARY OF THE INVENTION

### Technical Problem

The inventor of the invention etched a four-layer laminate film (multilayered laminate film) in which silicon oxide film layers and silicon nitride film layers were alternately stacked through a mask formed of an organic film using C₅HF₇ (unsaturated fluorohydrocarbon compound) used in Example 1 of Patent Document 1. As a result, the inventor found that the selectivity of the multilayered laminate film with respect to the mask is low, and the contact holes may be clogged by a deposited film.

The invention was conceived in view of the above situation. An object of the invention is to provide an etching method that can etch even a multilayered laminate film that includes four or more layers while ensuring high selectivity with respect to the mask and an excellent pattern shape, and preventing a situation in which contact holes are clogged by a deposited film.

### Solution to Problem

The inventor conducted extensive studies in order to solve the above problem. As a result, the inventor found that it is possible to etch even a multilayered laminate film that includes four or more layers while ensuring high selectivity with respect to the mask and an excellent pattern shape, and preventing a situation in which contact holes are clogged by a deposited film, by utilizing a fluorohydrocarbon compound gas having 4 carbon atoms that does not include an unsaturated bond as the etching gas.

One aspect of the invention provides the following etching method (see (1) to (5)).

(1) An etching method including etching a multilayered laminate film that includes at least one silicon oxide film layer and at least one silicon nitride film layer using an etching gas, the etching method simultaneously etching both the silicon oxide film layer and the silicon nitride film layer, the etching gas including a linear saturated fluorohydrocarbon compound represented by a formula (1): CₓH_{y}F_{z} (wherein x is 4, y is an integer equal to or larger than 4, and z is a positive integer, provided that y+z is 10).
(2) The etching method according to (1), wherein the etching gas further includes oxygen gas.
(3) The etching method according to (2), wherein the etching gas further includes one or more Group 0 gases selected from the group consisting of helium, argon, neon, krypton, and xenon.
(4) The etching method according to (1), wherein the multilayered laminate film is etched using an organic film provided thereon as a mask.
(5) The etching method according to (1), wherein the linear saturated fluorohydrocarbon compound is a compound selected from the group consisting of 2-fluoro-n-butane (C₄H₉F), 2,2-difluoro-n-butane (C₄H₈F₂), 1,1,1,3,3-pentafluoro-n-butane (C₄H₅F₅), and 1,1,1,4,4,4-hexafluoro-n-butane (C₄H₄F₆).

### Advantageous Effects of the Invention

According to one aspect of the invention, when forming a contact hole (hereinafter may be referred to as “hole”) having a high aspect ratio in a multilayered laminate film, it is possible to implement etching that forms a rectangular hole shape having an excellent sidewall shape (i.e., a hole shape in which an abnormal protrusion or the like is not formed on the sidewall, and the sidewall is smooth) while ensuring high selectivity with respect to the mask, and preventing a situation in which the holes are clogged by a deposited film.

### DESCRIPTION OF EMBODIMENTS

Exemplary embodiments of the invention are described in detail below.

An etching method according to one embodiment of the invention includes etching a multilayered laminate film that includes at least one silicon oxide film layer and at least one silicon nitride film layer using an etching gas, the etching method simultaneously etching both the silicon oxide film layer and the silicon nitride film layer, the etching gas including a linear saturated fluorohydrocarbon compound represented by a formula (1): CₓH_{y}F_{z} (wherein x is 4, and y and z are a positive integer, provided that y+z is 10, and y is equal to or larger than 4) (hereinafter referred to as “fluorohydrocarbon compound (1)”).

### Multilayered Laminate Film

The multilayered laminate film (workpiece) that is etched using the etching method according to one embodiment of the invention includes at least one silicon oxide film layer and at least one silicon nitride film layer. The multilayered laminate film is preferably a multilayered laminate film in which silicon oxide film layers and silicon nitride film layers are alternately stacked, and more preferably a multilayered laminate film in which four or more silicon oxide film layers and four or more silicon nitride film layers (etching target) are alternately stacked.

Specific examples of the multilayered laminate film include a multilayered laminate film in which sixty-four silicon oxide film layers and sixty-four silicon nitride film layers (etching target) are alternately stacked (128 layers in total).

The etching method according to one embodiment of the invention can etch even a multilayered laminate film (workpiece) that includes four or more layers while ensuring high selectivity with respect to the mask and an excellent pattern shape, and preventing a situation in which contact holes are clogged by a deposited film.

### Etching Gas

The etching method according to one embodiment of the invention utilizes a gas that includes the fluorohydrocarbon compound (1) as the etching gas.

The content of the fluorohydrocarbon compound (1) in the etching gas is set to be 1 to 20 vol % based on the total flow rate.

Specific examples of the fluorohydrocarbon compound (1) include a saturated fluorohydrocarbon represented by C₄H₉F, such as 1-fluoro-n-butane, 2-fluoro-n-butane, and 2-fluoro-2-methylpropane; a saturated fluorohydrocarbon represented by C₄H₈F₂, such as 1,1-difluoro-n-butane, 1,2-difluoro-n-butane, 1,3-difluoro-n-butane, 1,4-difluoro-n-butane, 2,3-difluoro-n-butane, 2,2-difluoro-n-butane, 1,3-difluoro-2-methylpropane, 1,2-difluoro-2-methylpropane, and 1,1-difluoro-2-methylpropane;

a saturated fluorohydrocarbon represented by C₄H₇F₃, such as 1,1,1-trifluoro-n-butane, 1,1,2-trifluoro-n-butane, 1,1,3-trifluoro-n-butane, 1,1,4-trifluoro-n-butane, 1,1,1-trifluoro-2-methylpropane, and 1,1,3-trifluoro-2-methylpropane;

a saturated fluorohydrocarbon represented by C₄H₆F₄, such as 1,1,1,4-tetrafluoro-n-butane, 1,2,3,4-tetrafluoro-n-butane, 1,1,1,2-tetrafluoro-n-butane, 1,2,3,3-tetrafluoro-n-butane, 2,2,3,3-tetrafluoro-n-butane, 1,1,3,3-tetrafluoro-2-methylpropane, 1,1,3-trifluoro-2-fluoromethylpropane, 1,1,2,3-tetrafluoro-2-methylpropane, 1,2,3-trifluoro-2-fluoromethylpropane, and 1,1,1,2-tetrafluoro-2-methylpropane;

a saturated fluorohydrocarbon represented by C₄H₅F₅, such as 1,1,1,3,3-pentafluoro-n-butane, 1,1,1,3,4-pentafluoro-n-butane, and 1,1,1,4,4-pentafluoro-n-butane; a saturated fluorohydrocarbon represented by C₄H₄F₆, such as 1,1,1,4,4,4-hexafluoro-n-butane, 1,1,1,3,4,4-hexafluoro-n-butane, and 1,1,1,3,3,3-hexafluoro-2-methylpropane; and the like.

Among these, 2-fluoro-n-butane (C₄H₉F), 2,2-difluoro-n-butane (C₄H₈F₂), 1,1,1,3,3-pentafluoro-n-butane (C₄H₅F₅), and 1,1,1,4,4,4-hexafluoro-n-butane (C₄H₄F₆) are preferable since the advantageous effects of the invention can be significantly achieved.

These fluorohydrocarbon compounds (1) may be used either alone or in combination. It is preferable to use one type of the fluorohydrocarbon compound (1) alone since the advantageous effects of the invention can be significantly achieved.

Many of the fluorohydrocarbon compounds (1) are known compounds, and may be produced using a known production method. For example, 2-fluoro-n-butane may be produced using the method described in J. Org. Chem., 44 (22), 3872 (1987), 2,2-difluoro-n-butane may be produced using the method described in JP-A-05-221892, JP-A-06-100475, or the like, 1,1,1,3,3-pentafluoro-n-butane may be produced using the method described in JP-A-05-171185, JP-A-08-198783, or the like, and 1,1,1,4,4,4-hexafluoro-n-butane may be produced using the method described in JP-A-05-155788, JP-A-08-003081, or the like.

A commercially available product may be used as the fluorohydrocarbon compound (1) either directly or after optional purification.

It is preferable that the fluorohydrocarbon compound (1) have high purity. The advantageous effects of the invention are more easily achieved by utilizing the fluorohydrocarbon compound (1) having high purity.

If the purity of the fluorohydrocarbon compound (1) is too low, the purity of the gas (i.e., the content of the fluorohydrocarbon compound (1)) may become uneven inside a container that is filled with the gas. Specifically, the purity of the gas may significantly differ between the initial stage and a stage when the amount of the gas has decreased.

In such a case, a large difference in performance may occur during dry etching between the initial stage and a stage when the amount of the gas has decreased, and a decrease in yield may occur when the method is applied to a factory production line.

Since a situation in which the purity of the gas becomes uneven inside a container can be prevented by increasing the purity of the gas, a difference in performance does not occur between the initial stage and a stage when the amount of the gas has decreased. This makes it possible to improve yield when the method is applied to a factory production line, and efficiently utilize the gas.

The fluorohydrocarbon compound (1) is put in an arbitrary container such as a cylinder in the same manner as a semiconductor gas, and used for etching described later.

The etching gas used for the etching method according to one embodiment of the invention preferably includes oxygen gas and/or nitrogen gas (more preferably oxygen gas) in addition to the fluorohydrocarbon compound (1).

High selectivity with respect to the mask can be achieved while preventing an etching stop phenomenon (that is considered to occur due to deposition of a reaction product at the bottom of a hole) by utilizing oxygen gas and/or nitrogen gas in addition to the fluorohydrocarbon compound (1).

Note that the expression “high selectivity with respect to the mask” means that the ratio (selectivity ratio) of the etching rate of the multilayered laminate film (etching target film) to the etching rate of the mask (etching exclusion target film) (i.e., (average etching rate of silicon oxide film and silicon nitride film)/etching rate of mask) is high.

The average etching rate of the silicon oxide film and the silicon nitride film is calculated using the following expression.

(2×(etching rate of silicon oxide film)×(etching rate of silicon nitride film))/((etching rate of silicon oxide film)+(etching rate of silicon nitride film))

The volume ratio (total volume ratio) ((total volume of oxygen gas and/or nitrogen gas)/volume of fluorohydrocarbon compound (1)) of oxygen gas and/or nitrogen gas to the fluorohydrocarbon compound (1) is preferably 0.1 to 50, and more preferably 0.5 to 30.

The etching gas preferably further includes at least one Group 0 gas selected from the group consisting of helium, argon, neon, krypton, and xenon. It is preferable that the etching gas include helium gas or argon gas from the viewpoint of availability.

It is possible to increase the plasma density and the etching rate by utilizing the Group 0 gas.

The volume ratio (volume of Group 0 gas/volume of fluorohydrocarbon compound (1)) of the Group 0 gas to the fluorohydrocarbon compound (1) is preferably 0.1 to 100, and more preferably 0.5 to 50.

### Etching Method

The term “etching” used herein in connection with the etching method according to one embodiment of the invention refers to a technique that etches a highly integrated fine pattern on a workpiece that is used when producing a semiconductor device or the like. Examples of etching include plasma etching. The term “plasma etching” used herein refers to a technique that applies a high-frequency electric field to an etching gas (reactive plasma gas) to effect a glow discharge and decompose the gaseous compound into chemically active ions and radicals, and effects etching by utilizing the chemical reactions.

Specifically, the etching gas is introduced into a processing chamber in which the workpiece is placed, and plasma is generated using a plasma generation device to effect etching in a plasma atmosphere.

The pressure inside the processing chamber into which the etching gas has been introduced is normally set to 0.0013 to 1300 Pa, and preferably 0.13 to 13 Pa.

The fluorohydrocarbon compound (1) is preferably introduced into the processing chamber at a rate of 1 to 50 sccm, and more preferably 5 to 20 sccm. Oxygen gas and/or nitrogen gas are/is preferably introduced into the processing chamber at a rate of 0 to 200 sccm, and more preferably 0 to 80 sccm. The Group 0 gas is preferably introduced into the processing chamber at a rate of 0 to 1000 sccm, and more preferably 0 to 400 sccm.

Examples of the plasma generation device include a helicon wave-type plasma generation device, a high frequency induction-type plasma generation device, a parallel plate-type plasma generation device, a magnetron-type plasma generation device, a microwave-type plasma generation device, and the like.

The plasma generation device applies a high-frequency electric field to the fluorohydrocarbon compound (1) contained in the processing chamber to effect a glow discharge and generate plasma.

The plasma density is not particularly limited. It is preferable to effect etching in a high-density plasma atmosphere having a plasma density of 10¹¹ cm⁻³ or more, and more preferably 10¹² to 10¹³ cm⁻³, in order to more reliably achieve the advantageous effects of the invention.

The temperature of the etching target substrate that is reached during etching is not particularly limited, but is preferably 0 to 300° C., more preferably 0 to 100° C., and still more preferably 0 to 80° C. The temperature of the substrate may be controlled by cooling or the like, or may not be controlled.

The multilayered laminate film is normally etched in a state in which a patterned mask is provided on the multilayered laminate film.

An organic film is normally used as the mask. An amorphous carbon film that exhibits high etching resistance is preferably used as the organic film.

Since the fluorohydrocarbon compound (1) has high selectivity with respect to the mask, it is possible to etch even a multilayered laminate film in which four or more silicon oxide film layers and four or more silicon nitride film layers are alternately stacked, while achieving an excellent sidewall shape, and preventing a situation in which the mask breaks, or holes are clogged by a deposited film.

### EXAMPLES

The invention is further described below by way of examples. Note that the invention is not limited to the following examples.

### Example 1

### (i) Calculation of Selectivity Ratio

A wafer in which a silicon oxide film (thickness: 2000 nm) was formed on the surface of a silicon substrate, a wafer in which a silicon nitride film (thickness: 1000 nm) was formed on the surface of a silicon substrate, and a wafer in which an amorphous carbon film (thickness: 200 nm) was formed on the surface of a silicon substrate, were placed inside the etching chamber of a parallel plate-type plasma etching apparatus.

After evacuating (2 Pa) the system, 2-fluoro-n-butane (C₄H₉F (fluorohydrocarbon compound (1-1) in Table 1)) (10 sccm), oxygen (30 sccm), and argon (200 sccm) were introduced into the etching chamber, and each wafer was etched under the following etching conditions.

### Etching Conditions

Power supplied to upper electrode from high-frequency power supply: 300 W
Power supplied to lower electrode from high-frequency power supply: 600 W
Electrode temperature: 0° C.

The etching rate (nm/min) of the wafer provided with the silicon oxide film, and the etching rate (nm/min) of the wafer provided with the silicon nitride film were calculated, and the average etching rate (nm/min) of the silicon oxide film and the silicon nitride film was calculated using the following expression.

(2×(etching rate of silicon oxide film)×(etching rate of silicon nitride film))/((etching rate of silicon oxide film)+(etching rate of silicon nitride film))

The etching rate (nm/min) of the amorphous carbon film (mask) was calculated, and the ratio (selectivity ratio) of the average etching rate of the silicon oxide film and the silicon nitride film to the etching rate of the amorphous carbon film was calculated using the following expression. The results are shown in Table 1.

(Average etching rate of silicon oxide film and silicon nitride film/etching rate of mask)

### (ii) Etching of Multilayered Laminate Film

A wafer in which an amorphous carbon film layer provided with a given hole pattern was formed on a four-layer laminate film (multilayered laminate film) in which a first silicon nitride film (thickness: 100 nm), a first silicon oxide film (thickness: 100 nm), a second silicon nitride film (thickness: 100 nm), and a second silicon oxide film (thickness: 100 nm) were sequentially stacked on a silicon substrate, was etched in the same manner as described above (see (i)).

After completion of etching, whether the disappearance of the mask (amorphous carbon film) had occurred or not was visually determined. The holes formed by etching were observed using a scanning electron microscope to determine whether or not the holes were clogged, and the pattern shape was evaluated. The results are shown in Table 1.

### Examples 2 to 4 and Comparative Examples 1 to 5

A wafer in which a silicon oxide film was formed on the surface of a silicon substrate, a wafer in which a silicon nitride film was formed on the surface of a silicon substrate, and a wafer in which an amorphous carbon film was formed on the surface of a silicon substrate, were etched, and the ratio (selectivity ratio) of the average etching rate of the silicon oxide film and the silicon nitride film to the etching rate of the amorphous carbon film was calculated (i) in the same manner as in Example 1, except that the fluorohydrocarbon compound shown below was used instead of 2-fluoro-n-butane (C₄H₉F). A wafer provided with a four-layer laminate film was etched, and whether the disappearance of the mask (amorphous carbon film) had occurred or not, whether or not the holes were clogged, and the pattern shape were determined (evaluated) (ii) in the same manner as in Example 1. The results are shown in Table 1.
Fluorohydrocarbon compound (1-2): 2,2-difluoro-n-butane (C₄H₈F₂)
Fluorohydrocarbon compound (1-3): 1,1,1,3,3-pentafluoro-n-butane (C₄H₅F₅)
Fluorohydrocarbon compound (1-4): 1,1,1,4,4,4-hexafluoro-n-butane (C₄H₄F₆)
Fluorohydrocarbon compound (2): difluoromethane (CH₂F₂)
Fluorohydrocarbon compound (3): 1,1,1,2,2,3,4,4,4-nonafluorobutane (C₄HF₉)
Fluorohydrocarbon compound (4): perfluorocyclobutane (C₄F₈)
Fluorohydrocarbon compound (5): hexafluoro-1,3-butadiene (C₄F₆)
Fluorohydrocarbon compound (6): 1,3,3,4,4,5,5-heptafluorocyclopentene (C₅HF₇)

TABLE 1

| | | | | | Comparative | Comparative | Comparative | Comparative | Comparative |
|---|---|---|---|---|---|---|---|---|---|
| | Example 1 | Example 2 | Example 3 | Example 4 | Example 1 | Example 2 | Example 3 | Example 4 | Example 5 |
| Fluorohydrocarbon | (1-1) | (1-2) | (1-3) | (1-4) | (2) | (3) | (4) | (5) | (6) |
| compound | | | | | | | | | |
| Etching rate of | 52.8 | 65.5 | 170.9 | 139.0 | 68.4 | 166.6 | 175.8 | 186.7 | 197.9 |
| silicon oxide film | | | | | | | | | |
| Etching rate of | 36.7 | 81.5 | 180.5 | 187.2 | 73.4 | 258.9 | 207.1 | 161.6 | 119.1 |
| silicon nitride film | | | | | | | | | |
| Average etching | 43.3 | 72.6 | 175.6 | 159.5 | 70.8 | 202.7 | 190.2 | 173.3 | 148.7 |
| rate | | | | | | | | | |
| Etching rate of | 2.6 | 1.0 | 2.9 | 20.5 | 41.0 | 138.4 | 123.0 | 69.7 | 46.8 |
| mask | | | | | | | | | |
| Selectivity ratio | 16.7 | 70.1 | 60.5 | 7.8 | 1.7 | 1.5 | 1.5 | 2.5 | 3.2 |
| Disappearance of | Did not | Did not | Did not | Did not | Occurred | Occurred | Occurred | Did not | Did not |
| mask | occur | occur | occur | occur | | | | occur | occur |
| Clogging of holes | Did not | Did not | Did not | Did not | Did not | Did not | Did not | Occurred | Occurred |
| | occur | occur | occur | occur | occur | occur | occur | | |
| Pattern shape | Good | Good | Good | Good | Good | Bad | Good | — | — |

In Examples 1 to 4 in which the fluorohydrocarbon compound (1) was used as the etching gas, selectivity with respect to the mask was high, and an excellent pattern shape was obtained by etching while preventing a situation in which the contact holes were clogged by a deposited film (see Table 1).

In Comparative Examples 1 to 3 in which the fluorohydrocarbon compound (2), (3), or (4) was used as the etching gas, the amorphous carbon film disappeared due to etching since the selectivity ratio was low, and the second silicon oxide film was etched in an area in which the second silicon oxide film was masked with the amorphous carbon film. In Comparative Example 2, the silicon nitride film was also etched in the horizontal direction, and a poor sidewall shape was obtained since the etching rate of the silicon nitride film was significantly higher than the etching rate of the silicon oxide film.

In Comparative Examples 4 and 5 in which the fluorohydrocarbon compound (5) or (6) including an unsaturated bond was used, the holes were clogged by a deposited film during etching, and the wafer provided with the four-layer laminate film could not be completely etched.

1. An etching method comprising etching a multilayered laminate film that includes at least one silicon oxide film layer and at least one silicon nitride film layer using an etching gas, the etching method simultaneously etching both the silicon oxide film layer and the silicon nitride film layer, the etching gas comprising a linear saturated fluorohydrocarbon compound represented by a formula (1): CₓH_{y}F_{z} (wherein x is 4, y is an integer equal to or larger than 4, and z is a positive integer, provided that y+z is 10).

2. The etching method according to claim 1, wherein the etching gas further comprises oxygen gas.

3. The etching method according to claim 2, wherein the etching gas further comprises one or more Group 0 gases selected from a group consisting of helium, argon, neon, krypton, and xenon.

4. The etching method according to claim 1, wherein the multilayered laminate film is etched using an organic film provided thereon as a mask.

5. The etching method according to claim 1, wherein the linear saturated fluorohydrocarbon compound is a compound selected from a group consisting of 2-fluoro-n-butane (C₄H₉F), 2,2-difluoro-n-butane (C₄H₈F₂), 1,1,1,3,3-pentafluoro-n-butane (C₄H₅F₅), and 1,1,1,4,4,4-hexafluoro-n-butane (C₄H₄F₆).
